(19) United States
(12) Patent Application Publication
(10) Pub. No.: US 2006/0072282 A1
(43) Pub. Date: Apr. 6, 2006

(54) Dielectric thin film, thin film capacitor element, and method for manufacturing thin film capacitor element

(75) Inventors: Kiyoshi Uchida, Tokyo (JP); Kenji Horino, Tokyo (JP); Hitoshi Saita, Tokyo (JP)

Correspondence Address: OLIFF & BERRIDGE, PLC, P.O. BOX 19928, ALEXANDRIA, VA, 22320, US

(73) Assignee: TDK CORPORATION, Tokyo (JP)

(21) Appl. No.: 11/235,051

(22) Filed: Sep. 27, 2005

(30) Foreign Application Priority Data
Sep. 29, 2004 (JP) P2004-284750

(51) Int. Cl. H01G 4/20

(52) U.S. Cl. 361/320

(57) ABSTRACT

The present invention provides a dielectric thin film whose composition is expressed by the formula (Ba₁₋ₓSrₓ)_{y}TiO₃ (0.18≦x≦0.45, 0.96≦y≦1.04), and whose peak intensity ratio I(100)I(110) is from 0.02 to 2.0 when I(100) is the peak intensity of the diffraction line of the (100) plane, and I(110) is the peak intensity of the diffraction line of the (110) plane in an X-ray diffraction chart of the dielectric thin film.

### BACKGROUND OF THE INVENTION

1. Field of the Invention

The present invention relates to a dielectric thin film and a thin film capacitor element that have a high dielectric constant, good temperature characteristics of the dielectric constant, and good leak characteristics, and a method for manufacturing the thin film capacitor element.

2. Description of the Related Art

As electronic devices have rapidly become smaller and higher in performance in recent years, the electronic circuitry used in these devices has increased in density and integration, and there has been a need for even smaller capacitor elements and other such circuit elements that are essential to various electronic circuits. For instance, thin film capacitors that make use of dielectric thin films have come to be widely used in integrated circuits with active elements such as transistors.

SiO₂, Si₃N₄, and other such materials have been used in the past for thin film capacitors, but from the standpoint of today's capacitance density, a problem is that a satisfactory dielectric constant cannot be obtained for capacitor materials used in next-generation DRAMs (gigabyte generation). Also, decreasing the thickness of a dielectric is another possible way to obtain high capacitance in addition to using a material with a high dielectric constant, but this decreased thickness sometimes produces pores in a dielectric film, which result in inferior leak characteristic and dielectric strength.

Meanwhile, it is known that a dielectric thin film with improved leak characteristics and higher dielectric constant can be obtained by using (Ba,Sr)TiO₃ (BST) as a material having a relatively high dielectric constant (see Japanese Laid-Open Patent Application H7-17713, for example). Japanese Laid-Open Patent Application H7-17713 discloses the use of a perovskite oxide expressed by the chemical formula (B,Sr)_{y}TiO₃, in which a high dielectric constant and good leak characteristics are achieved at a film thickness of about 200 nm by using a composition in which 1.00<y<1.20.

The above-mentioned BST does have a high dielectric constant but a dielectric material of this type is not a temperature compensating material, so its temperature coefficient is high (for example, with bulk BST, the electrostatic capacitance at 80° C. exhibits a temperature change that is from 1000 to 4000 ppm/° C. lower than the electrostatic capacitance at 20° C.), and when a material such as this is used to make a thin film capacitor element, the temperature characteristics of the dielectric constant sometimes suffer. In particular, difficulties are encountered when such materials are disclosed close to an LSI chip or the like, which can reach high temperatures of 80° C. or above.

Known dielectric materials with improved temperature characteristics include bulk materials such as lanthanum titanate (La₂O₃.2TiO₂), zinc titanate (ZnO.TiO₂), magnesium titanate (MgTiO₃), titanium oxide (TiO₂), bismuth titanate (Bi₂O₃.2TiO₂), calcium titanate (CaTiO₃), and strontium titanate (SrTiO₃), which are used mainly in laminated ceramic capacitors.

However, with dielectric compositions used for temperature compensation in laminated ceramic capacitors and so forth, the dielectric constant tends to decease (to less than 40, for example) when the temperature coefficient decreases (such as not more than an absolute value of 100 ppm/° C.), and conversely, the temperature coefficient increases (such as not less than an absolute value of 750 ppm/° C.) when the dielectric constant tends to increase (to not less than 90, for example), making it difficult to use such compositions directly as thin film capacitors.

In view of this, to improve the temperature characteristics of a thin film capacitor, there has been proposed a thin film capacitor in which a dielectric layer is formed as a thin film between a pair of electrodes, wherein the dielectric layer comprises a first layer whose temperature coefficient is positive and a second layer whose temperature coefficient is negative, and the temperate coefficient of the thin film capacitor is between −100 ppm/° C. and +100 ppm/° C. (see Japanese Laid-Open Patent Application H9-293629, for example). The temperature coefficient of a thin film capacitor is lowered by canceling out the positive and negative temperature coefficients by combining dielectric thin films having positive and negative temperature coefficients.

With the same objective in mind, it has been proposed that temperature coefficient of a thin film capacitor be lowered by canceling out positive and negative temperature coefficients by interposing at least two dielectric thin films with different dielectric constants (a first dielectric film whose capacitance coefficient has an absolute vale of no more than 50 ppm/° C., and a second dielectric thin film whose capacitance temperature coefficient is negative and has an absolute value of at least 500 ppm/° C.) in between a pair of electrodes (see Japanese Laid-Open Patent Application 2002-75783, for example).

### SUMMARY OF THE INVENTION

However, the BST-based dielectric thin film discussed in Japanese Laid-Open Patent Application H7-17713 is said to have good insulation characteristics and a high dielectric constant within a specific compositional range (such as the (Ba_{0.5}Sr_{0.5})_{y}TiO₃ (1.00<y≦1.20) given in the examples), but there is no mention whatsoever regarding the temperature characteristics of the dielectric constant.

The inventions of Japanese Laid-Open Patent Application H9-293629 and Japanese Laid-Open Patent Application 2002-75783, meanwhile, at least two dielectric thin film layers to be formed, and the problem with increasing the number of thin film formation steps is that it adversely affects productivity. Furthermore, it is difficult to achieve the dielectric high dielectric constant and leak characteristics in addition to good temperature characteristics. Moreover, forming the various dielectric layers by sol-gel method is given as an example in Japanese Laid-pen Patent Application H9-293629, but the heat treatment performed for crystallization causes inter-diffusion at the interface between the two layers, and it is difficult to obtain the targeted temperature characteristics in these layers.

In view of this, it is an object of the present invention to provide a dielectric thin film that is a BST-based dielectric thin film, has good dielectric constant temperature characteristics (the absolute value of the temperature coefficient is extremely small), and is easy to manufacture. It is another object of the present inventions to provide a dielectric thin film with a high dielectric constant and good leak characteristics.

As a result of diligent study into BST thin film materials, the inventors discovered that while it is generally held that BST bulk materials have a high temperature coefficient as mentioned above, when a thin film of 500 nm or less was produced in the course of trial and error, the electrical characteristics of this film did not necessarily match the tendency of bulk materials. Specifically, the inventors arrived at the present invention upon discovering that even with a BST material, a dielectric thin film that has good temperature characteristics, a high dielectric constant and a low leakage current density can be obtained by controlling the composition to a specific range, and controlling the ratio of the diffraction line peak intensity of the (100) plane and the (110) plane to a specific range.

More specifically, the present invention is a dielectric thin film whose composition is expressed by the formula (Ba₁₋ₓSrₓ)_{y}TiO₃ (0.18≦x≦0.45, 0.96≦y≦1.04), and whose peak intensity ratio I(100)/(110) is from 0.02 to 2.0 when I(100) is the peak intensity of the diffraction line of the (100) plane, and I(110) is the peak intensity of the diffraction line of the (110) plane in an X-ray diffraction chart of the dielectric thin film. According to this invention, a dielectric thin film tat has an extremely low temperature coefficient, a high dielectric constant, and good leak characteristics, is provided. More specifically, a dielectric thin film in which the absolute value of the dielectric constant temperature coefficient is no more than 600 ppm/° C., the dielectric constant at 25° C. is at least 200, and the leakage current density at 25° C. is no more than 1×10⁻⁶ A/cm² is provided.

Also, this dielectric thin film can be ed favorably in a thin film capacitor element. More specifically, the thin film capacitor element according to the present invention has a dielectric thin film and a pair of electrodes that sandwich this dielectric thin film wherein the dielectric thin film has a composition expressed by the formula (Ba₁₋ₓSrₓ)_{y}TiO₃ (0.18≦x≦0.45, 0.96≦y≦1.04), and has a peak intensity ratio I(100)/I(110) of from 0.02 to 2.0 when I(100) is the peak intensity of the diffraction line of the (100) plane, and I(110) is the peak intensity of the diffraction line of the (110) plane in an X-ray diffraction chart. According to this invention, a dielectric thin film that has an extremely low temperature coefficient, a high dielectric constant and good leak characteristics, is provided. More specifically, a dielectric film in which the absolute value of the dielectric constant temperature coefficient is no more than 600 ppm/° C., the dielectric constant at 25° C. is at least 200, and the leakage current density at 25° C. is no more than 1×10⁻⁶ A/cm² is provided.

The method for manufacturing a thin film capacitor element according to the present invention comprises the steps of forming a dielectric thin film, whose composition is expressed by the formula (Ba₁₋ₓSrₓ)_{y}TiO₃ (0.18≦x≦0.45, 0.96≦y≦1.04), on a lower electrode formed on a substrate, by sputtering at a substrate temperature over 400° C. and no higher than 800° C., and annealing the obtained dielectric thin film at a temperature over 600° C. and no higher than 900° C. The above-mentioned peak intensity can be controlled by controlling the composition, the substrate temperature, and the annealing temperature within the above-mentioned compositional range. Namely, according to the above method, a dielectric thin film that has an extremely low temperature coefficient, a high dielectric constant, and good leak characteristics can be manufactured. More specifically, according to the present invention, a thin film capacitor element having a dielectric thin film in which the absolute value of the dielectric constant temperature coefficient is no more than 600 ppm/° C., the dielectric constant at 25° C. is at least 200, and the leakage current density at 25° C. is no more than 1×10⁻⁶ A/cm² can be manufactured.

### BRIEF DESCRIPTION OF THE DRAWINGS

FIG. 1 is a schematic sectional view of the capacitor element according to the present invention.

### DESCRIPTION OF THE PREFERRED EMBODIMENT

The dielectric thin film according to the present invention has a composition expressed by the formula (Ba₁₋ₓSrₓ)_{y}TiO₃ (0.18≦x≦0.45, 0.96≦y≦1.04), and its peak intensity ratio I(100)/I(110) is from 0.02 to 2.0 when I(100) is the pea intensity of the diffraction line of the (100) plane, and I(110) is the peak intensity of the diffraction line of the (110) plane in an X-ray diffraction chart of the dielectric thin film. According to this invention, a dielectric thin film that has an extremely low temperature coefficient, a high dielectric constant, and good leak characteristics is provided. More specifically, a dielectric thin film in which the absolute value of the dielectric constant temperature coefficient is no more than 600 ppm/° C., the dielectric constant at 25° C. is at least 200, and the leakage current density at 25° C. is no more than 1×10⁻⁶ A/cm² is provided. The temperature coefficient will tend to be high if x is either too small or too large. The temperature coefficient will also tend to be high if y is too large, and the dielectric constant will tend to be low if y is too small. Thus, when the composition is expressed by the formula (Ba₁₋ₓSrₓ)_{y}TiO₃, it is preferable if 0.18≦x≦0.30 and 0.98≦y≦1.00.

When the peak intensity in an X-ray diffraction chart of the dielectric film is within the range given above, the dielectric constant will be high, the leakage current density will be low, and the temperature coefficient of the dielectric constant will be small. The technological reason for this is not clear, but it was discovered experimentally that there is some kind of relation between temperature characteristics and the orientation of the (100) plane. Specifically, it was found that whew annealing or another such heat treatment is performed after the formation of a BST thin film with a specific composition, the temperature characteristics of the dielectric constant vary simultaneously with fluctuations mainly in the peak intensity (I(100)). With a dielectric thin film whose composition is expressed by the formula (Ba₁₋ₓSrₓ)_{y}TiO₃ (0.18≦x≦0.45, 0.96≦y≦1.04), the temperature coefficient can be kept especially small by keeping the peak intensity ratio within the above range. In this specification, the orientation of the (100) plane being focused on is expressed by the ratio between the peak intensities I(100) and I(110), that is, by the peak intensity ratio I(100)/I(110). Crystal orientation is generally calculated by Lotgering's^{[1]} method, but herein, for the sake of simplicity, the orientation of the (100) plane will be expressed as the peak intensity ratio on the basis of the main peak I(110) in bulk.

It is preferable for the dielectric constant temperature coefficient to be as small as possible. More specifically, the absolute value of the dielectric constant temperature coefficient is preferably no more than 400 ppm/° C., and even more preferably the absolute value is no more than 200 ppm/° C. The dielectric constant at 25° C. is preferably as high as possible, with 300 or higher being especially good. The leakage current density at 25° C. is preferably as low as possible, with 5×10⁻⁷ A/cm² or lower being especially good.

As long as the dielectric thin film has the above composition and its peak intensity ratio is controlled as above, the dielectric thin film according to the present invention can be produced by any thin film formation process, such as sputtering or another such vapor phase method, or MOD or another such solution method, but producing it by sputtering is preferable because it will be easier to adjust the composition and peak intensity ratio.

When the above-mentioned dielectric thin film is formed by sputtering, a substrate (when a capacitor element is to be formed, a substrate having an electrode formed on its surface) is heated to no higher than 600° C., and a BST target is sputtered under reduced pressure in an oxidative atmosphere, produced by introducing argon gas mixed with no more man 50 vol % oxidative gas into a chamber.

When the film is formed by sputtering, the peak intensity ratio I(100)/I(110) tends to rise as the substrate temperature rises, and the temperature coefficient of the dielectric constant also tends to rise. In view of this, with the present invention, the film is formed in a state of reduced peak intensity ratio I(100)/I(110), and as will be discussed below, annealing is preferably performed to adjust the peak intensity ratio I(100)/I(110) to within the optimal range, that is to adjust the temperature coefficient of the dielectric constant to within a specific range. More specifically, the film formation temperature is over 400° C. and no higher than 800° C., and preferably no lower than 550° C. and no higher than 750° C. Also, since the dielectric thin film is formed in an oxidate atmosphere, there is no loss of oxygen from the crystal structure of the BST, so leakage current density decreases. The oxidative gas used here can be oxygen gas, nitrous oxide, or the like. The pressure in the chamber is preferably from 0.3 to 4 Pa.

The target used here may be a BST target with the desired composition, or BT and ST targets may be used. The composition of the target may be adjusted as needed depending on the conditions involved.

The film thickness is preferably 500 nm or less, and even more preferably 40 to 200 nm. If the film is too thin, the dielectric constant will decease and capacitance will be low when a capacitor element is formed. Dielectric strength will also tend to be lower. If the film is too thick capacitance will be low when a capacitor element is formed. The film formation rate is 10 nm/min or less, and preferably 6 nm/min, and even more preferably 3 nm/min. A higher film formation rate is preferable because productivity is enhanced, but the lower the film formation rate, the lower the leakage current density will be.

After the dielectric thin film has been formed on the substrate, annealing is preferably performed at not less than the film formation temperature to adjust the peak intensity ratio I(100)/I(110), that is, the temperature coefficient of the dielectric constant. For a given composition, when the film is formed at a lower temperature, the peak intensity ratio I(100)/I(110) tends to be lower, and the temperature coefficient may be outside the specified range. Annealing increases the peak intensity ratio I(100)/I(110), and as a rest, the temperature coefficient can be adjusted to within the optimal range. Furthermore, annealing also raises the dielectric constant. However, if the annealing is performed at a temperature over 900° C., the peak intensity ratio I(100)/I(110) will be over 2.0, so the temperature coefficient will be outside the specified range. Thus, when an annealing treatment is performed, it is preferably performed over the film formation temperature but no higher than 900° C. It is also preferable for the annealing to be performed in an oxide atmosphere. Performing it in an oxidative atmosphere prevents oxygen loss and reduces leakage current density.

The dielectric thin film according to the present invention can be used to advantage as a thin film capacitor element. This thin film capacitor element may comprise just one dielectric thin film layer. In this case, the above thin film capacitor element is obtained by forming a lower electrode layer, a dielectric thin films and an upper electrode layer in that order on a substrate. The thin film capacitor element may be a laminated thin film capacitor element having a multilayer dielectric thin film in which a plurality of dielectric thin films and internal electrodes are provided between a lower electrode and an upper electrode.

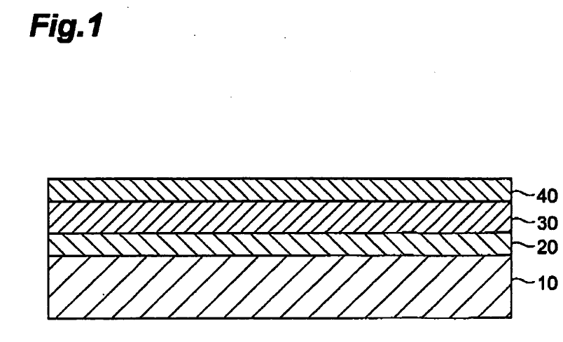

A thin film capacitor element comprising just one dielectric thin film layer will now be described in detail with reference to FIG. 1. FIG. 1 is a schematic tonal view of the thin film capacitor element according to the present invention.

A substrate 10 on which the dielectric thin film is to be formed may be a silicon substrate, an alumina or other ceramic substrate, a glass-ceramic substrate, a glass substrate, sapphire, MgO, SrTiO₃, or other such single crystal substrate, an Fe—Ni alloy or other metal substrate, or any other substrate which is chemically and thermally stable, generates little stress, and maintains surface smoothness. Of these, it is preferable to use a silicon substrate because the substrate surface smoothness will be better. When a silicon substrate is used, a thermal oxidation film (SiO₂ film) is preferably formed on the surface thereof to ensure electrical insulation. A thermal oxidation film is formed by heating the silicon substrate to a high temperature and oxidizing the silicon substrate face in an oxidative atmosphere.

A lower electrode layer 20 is formed over the substrate 10. There are no particular restrictions on the material of the lower electrode layer 20, as long as it is electroconductive, but examples include gold, platinum, silver, iridium, ruthenium, cobalt, nickel, iron, copper, aluminum, and other metals and alloys of these, silicon, GaAs, GaP, InP, SiC, and other semiconductors, and ITO, ZnO, SnO₂, and other conductive metal oxides. However, at least the lower conductor is preferably an oxidation-resistant metal such as gold or platinum because it will be subjected to heat treatment in an oxidative atmosphere when the dielectric thin film is formed by sputtering.

Sputtering or another vapor phase method can be used to form the lower electrode layer 20. There are no particular restrictions on the thickness of the lower electrode layer 20, but at least 50 nm is preferable.

An adhesion layer may be formed (not shown) prior to the formation of the lower electrode layer in order to improve the fit between the substrate 10 and the lower electrode layer 20. This adhesion layer can be made from an oxide or nitride of titanium, tantalum, cobalt, nickel, hafnium, molybdenum, tungsten, or the like, for example. CVD or another such vapor deposition method can be used to form the adhesion layer.

A dielectric thin film 30 is then formed over the lower electrode layer 20. As mentioned above, the material of the dielectric thin film 30 has a composition expressed by the formula (Ba₁₋ₓSrₓ)_{y}TiO₃ (0.18≦x≦0.45, 0.96≦y≦1.04). If we let I(100) be the peak intensity of the diffraction line of the (100) plane, and I(110) be the peak intensity of the diffraction line of the (110) plane in an X-ray diffraction chart, it is preferable for the peak intensity ratio I(100)/(110) to be from 0.02 to 2.0. The use of this material makes it possible to obtain an element whose dielectric constant temperature coefficient is small, the dielectric constant is large, and the leakage current density is low. The dielectric thin film 30 is formed by the method discussed above.

Next, an upper electrode layer 40 is formed over the dielectric thin film 30. There are no particular restrictions on the material of the upper electrode layer 40 as long as it is electroconductive, just as with the material of the lower electrode layer 20, and the conductive materials listed above can be used. A passivation layer (protective layer; not shown) is formed as needed. The material of the passivation layer can be SiO₂, Al₂O₃, or another inorganic material, or an epoxy resin, a polyamide resin, or another organic material. Every time a layer is formed, it may be formed in a specific pattern by photolithography.

### EXAMPLES

The present invention will now be described in further detail through examples, but the present invention is not to the following examples.

A 20 nm TiO₂ film was formed as an adhesion layer over a silicon substrate on whose surface a thermal oxidation film (SiO₂) had been formed. A lower electrode layer was then formed by sputtering over the adhesion layer. The electrode material was platinum, and the thickness was 100 to 150 nm. A dielectric thin film with the composition shown in Table 1 was then formed by sputtering with a BST target of a specific composition over the lower electrode layer. This film was formed in a mixed gas atmosphere containing argon gas and 10 to 25 vol % oxygen gas, at a substrate temperature of 550° C., a film formation pressure of 0.3 to 4 Pa, an it power of 1.3 to 1.8 W/cm², and a film formation rate of 4 to 5 nm/min. The thickness of the dielectric thin film was from 100 to 140 nm.

Thin films of various compositions were then annealed in an oxidative atmosphere. This annealing was performed for 30 minutes at four different temperatures (600, 800, 850, and 900° C.) in an oxygen gas flow. An upper electrode layer was then formed over the dielectric thin film. The electrode material was platinum, and the thickness was 100 to 150 nm. The opposing electrode diameter was 1.0 mm.

The samples in Table 1 (sample Nos. 1 to 13) were evaluated for dielectric constant, tan δ, leakage current density, and temperature coefficient of dielectric constant.

The dielectric constant (no units) was calculated from the electrode dimensions and the distance between electrodes of a capacitor sample, and the electrostatic capacitance measured at room temperature (25° C.) and a measurement frequency of 1 kHz (AC 1.0 V), using a digital LCR meter (4194A made by YHP). tan δ was measured under the same conditions as electrostatic capacitance above. The leakage current density (A/cm²) was measured at room temperature (25° C.) and an electric field strength of 100 kV/cm². The temperature characteristics of the dielectric constant were calculated as follows. The dielectric constant of a capacitor sample was measured under the above conditions, the maximum and minimum dielectric constants (Δε) of the dielectric constant versus temperature over a temperature range of 25 to 125° C. were measured, and the temperate coefficient (ppm/° C.) was calculated.

Each sample was measured with an X-ray (Cu K α ray) diffraction apparatus (RINT2000 made by Rigaku), at an X-ray generation level of 50 kV to 300 mA, a scanning range of 10 to 60°, and a scanning rate of 4°/minute, the peak intensity of the (100) crystal plane (I(100)) and the peak intensity of the (110) crystal plane (I(110)) were measured, and I(100)/I(110) (peak intensity ratio) was calculated. These results are shown in Table 1.

TABLE 1

| | | | | | | | | | Dielectric | Peak |
|---|---|---|---|---|---|---|---|---|---|---|
| | Dielectric thin | | | | | | | Leak | constant | intensity |
| | film composition | | Substrate | Annealing | Film | | | current | temp. | ratio |
| Sample | (Ba₁₋ₓSrₓ)_{y}TiO₃ | | temperature | temp. | thickness | Dielectric | tan δ | density | coefficient | I(100)/ |
| No. | x | y | (° C.) | (° C.) | (nm) | constant | (%) | (A/cm²) | (ppm/° C.) | I(110) |
| 1 | 0.19 | 1.00 | 600 | 800 | 105 | 333 | 2.9 | 2.3 × 10⁻⁷ | 160 | 0.4 |
| 2 | 0.19 | 1.00 | 600 | 850 | 105 | 477 | 4.1 | 4.2 × 10⁻⁷ | 130 | 2.0 |
| 3 | 0.27 | 0.99 | 550 | 800 | 100 | 419 | 0.4 | 6.1 × 10⁻⁸ | −154 | 0.051 |
| 4 | 0.27 | 0.99 | 550 | 850 | 100 | 475 | 2.5 | 3.3 × 10⁻⁸ | −232 | 0.160 |
| 5 | 0.27 | 0.99 | 550 | 900 | 100 | 498 | 2.2 | 3.6 × 10⁻⁸ | 122 | 0.520 |
| 6 | 0.45 | 1.03 | 600 | 800 | 134 | 326 | 2.5 | 3.4 × 10⁻⁷ | −530 | 0.020 |
| 7 | 0.45 | 1.03 | 600 | 850 | 134 | 448 | 4.3 | 2.1 × 10⁻⁷ | −595 | 0.032 |
| *8 | 0.54 | 1.01 | 600 | 800 | 130 | 342 | 2.0 | 1.0 × 10⁻⁷ | −1070 | 0.010 |
| *9 | 0.54 | 1.01 | 600 | 850 | 130 | 370 | 2.0 | 1.1 × 10⁻⁷ | −1170 | 0.011 |
| *10 | 0.54 | 1.01 | 600 | 900 | 130 | 428 | 2.6 | 1.5 × 10⁻⁷ | −1120 | 0.010 |
| *11 | 0.28 | 1.02 | 400 | 800 | 140 | 400 | 15 | 3.5 × 10⁻⁶ | −1500 | 0.010 |
| 12 | 0.29 | 1.03 | 750 | 600 | 100 | 463 | 2 | 1.5 × 10⁻⁷ | −300 | 0.71 |
| 13 | 0.29 | 1.03 | 800 | 600 | 103 | 518 | 2 | 8.0 × 10⁻⁷ | −550 | 0.65 |

*Comparative Example

As a result, favorable values were obtained in every category: the absolute value of the dielectric constant temperature coefficient within a compositional range of (Ba₁₋ₓSrₓ)_{y}TiO₃ (0.18≦x≦0.45, 0.96≦y≦1.04) (sample Nos. 1 to 7 and Nos.12 and 13 was 600 ppm/° C. or less, the dielectric constant was at least 200, and the leakage current density was no more than 1×10⁻⁶ A/cm². As the annealing temperature rose, the peak intensity ratio I(100)/I(110) increased, and the temperature coefficient also tended to decrease. This tells us that the peak intensity ratio I(100)/I(110), that is, the temperature coefficient, can be adjusted with the annealing temperature. Furthermore, a good temperature coefficient was obtained by adjusting the peak intensity ratio I(100)/I(110) to within a range of 0.02 to 2.0.

On the other hand, with sample Nos. 8 to 10 (comparative examples), the dielectric constant was at least 200 and the leakage current density was no more than 1×10⁻⁶ A/cm², but the temperature coefficient has a large absolute value of −1000 ppm/° C. or less. Also, the peak intensity ratio I(100)/I(110) was only about 0.010 or 0.011, and there was no change with the annealing temperature. Also, with sample No. 11 (comparative examples), the dielectric constant was at least 200, but the leakage curt density was over 1×10⁻⁶ A/cm², and the temperature coefficient has a large absolute value of −1000 ppm/° C. or less. Also, the peak intensity ratio I(100)/I(110) was only 0.010, and there was no change with the annealing temperature.

According to the present invention, a dielectric thin film and thin film capacitor element that have an extremely low temperature coefficient, a high dielectric constant, and good leak characteristics, are provided. More specifically, a dielectric thin film and thin film capacitor element in which the absolute value of the dielectric constant temperature coefficient is no more than 600 ppm/° C., the dielectric constant at 25° C. is at least 200, and the leakage current density at 25° C. is no more than 1×10⁻⁶ A/cm² are provided. The dielectric thin film and thin film capacitor element according to the present invention can be use, for example, in integrated circuits with active elements such as transistors.

What is claimed is:

1. A dielectric thin film, whose composition is expressed by the formula (Ba₁₋ₓSrₓ)_{y}TiO₃ (0.18≦x≦0.45, 0.96—y≦1.04), and whose peak intensity ratio I(100)/I(110) is from 0.02 to 2.0 when I(100) is the peak intensity of the diffraction line of the (100) plane, and I(110) is the peak intensity of the diffraction line of the (110) plane in an X-ray diffraction chart.

2. A dielectric thin film according to claim 1, wherein x and y meet the following formula:
0.18≦x≦0.30,
0.98≦y≦1.00

3. A dielectric thin film according to claim 1, wherein the dielectric thin film has a film thickness of 500 nm or less.

4. A thin film capacitor element having a dielectric thin film and a pair of electrodes that sandwich this dielectric thin film, wherein the dielectric thin film has a composition expressed by the formula (Ba₁₋ₓSrₓ)₃TiO₃ (0.18≦x≦0.45, 0.96≦y≦1.04), and has a peak intensity ratio I(100)/I(110) of from 0.02 to 2.0 when I(100) is the peak intensity of the diffraction line of the (100) plane, and I(110) is the peak intensity of the diffraction line of the (110) plane in an X-ray diffraction chart.

5. A thin film capacitor element according to claim 4, wherein x and y meet the following formula:
0.18≦x≦0.30,
0.98≦y≦1.00.

6. A thin film capacitor element according to claim 4, where the dielectric thin film has a film thickness of 500 nm or less.

7. A method for manufacturing a thin film capacitor element, comprising the steps of:
forming a dielectric thin film, whose composition is expressed by the formula (Ba₁₋ₓSrₓ)_{y}TiO₃ (0.18≦x≦0.45, 0.96≦y≦1.04), on a lower electrode formed on a substrate, by sputtering at a substrate temperature over 400° C. and no higher than 800° C.; and
annealing the obtained dielectric thin film at a temperature over 600° C. and no higher than 900° C.

8. A method for manufacturing a thin film capacitor element according to claim 7, wherein the dielectric thin film is formed at a film forming rate of 10 nm/minutes or less.

9. A method for manufacturing a thin film capacitor element according to claim 7, wherein the dielectric thin film is annealed at an oxidative atmosphere.
